(19) United States
(12) Patent Application Publication
(10) Pub. No.: US 2026/0173782 A1
(43) Pub. Date: Jun. 18, 2026

(54) ANGLED IMPLANT FOR PATTERNING FEATURE SURFACE ROUGHNESS IMPROVEMENT

(71) Applicant: Applied Materials, Inc., Santa Clara, CA (US)

(72) Inventors: John Hautala, Beverly, MA (US); Charith Nanayakkara, Gloucester, MA (US); Swasti Bhatia, Gloucester, MA (US)

(73) Assignee: Applied Materials, Inc., Santa Clara, CA (US)

(21) Appl. No.: 18/985,814

(22) Filed: Dec. 18, 2024

(51) Int. Cl. H01L 21/265; H01L 21/027; H01L 21/3065

(52) U.S. Cl. CPC H10P 30/222; H10P 50/242; H10P 76/2041

(57) ABSTRACT

Disclosed herein are approaches for using an angled ion beam treatment for patterning feature surface roughness improvement. In one approach, a method may include providing a plurality of patterned features over a stack of layers on a semiconductor substrate, wherein each of the plurality of patterned features includes a first sidewall and a second sidewall, and wherein an area of roughness is present along the first sidewall or the second sidewall. The method may further include performing an ion beam treatment to the plurality of patterned features by delivering ions at a non-zero angle relative to a perpendicular to a plane defined by an upper surface of the plurality of patterned features.

### FIELD OF THE DISCLOSURE

The present disclosure relates to semiconductor device patterning and, more particularly, to an angled ion treatment for patterning feature surface roughness improvement.

### BACKGROUND OF THE DISCLOSURE

Patterning features in layered stacks of materials is widely used for creating 2D and 3D patterns in semiconductor devices. Lithography is one such approach to creating these patterned features, and involves deposition of an underlayer and a film (photoresist) over the underlayer. These films may include some chemical additives/aids to enable dose reduction. The process may continue with irradiation of the film with a selected pattern by an energy source (e.g., exposure), and removal (e.g., etch) of exposed or non-exposed regions of the film by development processes. A bake may be carried out to drive off remaining developer. After patterning of the resist material, the desired features are transferred into the layer stack via etching processes.

Extreme ultraviolet (EUV) lithography operations enable smaller pitch features but have some drawbacks. For example, directly patterning sub-20 nm features results in increased line edge roughness (LER) and line width roughness (LWR) for line/space features due to the stochastic effects of reduced photon counts associated with EUV and high-numerical aperture (NA) lithography systems. LER and LWR can result in device defects, which negatively impact performance and yield.

It is desirable to improve the uniformity of post-exposure features and to transfer those improvements into the final etched features to decrease device defectivity and increase yield.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include providing a plurality of patterned features over a stack of layers on a semiconductor substrate, wherein each of the plurality of patterned features includes a sidewall, and wherein an area of roughness is present along the sidewall of at least one patterned feature of the plurality of patterned features. The method may further include performing an ion beam treatment to the plurality of patterned features by delivering ions at a non-zero angle relative to a perpendicular to a plane defined by the semiconductor substrate, wherein the ions impact the area of roughness.

In another aspect, a method for minimizing patterning feature surface roughness may include providing a plurality of patterned features over the stack of layers on a semiconductor substrate, wherein each of the plurality of patterned features includes a first sidewall and a second sidewall, and wherein an area of roughness is present along the first sidewall or the second sidewall of at least one patterned feature of the plurality of patterned features. The method may further include performing an ion beam treatment to the plurality of patterned features by delivering ions at a non-zero angle relative to a perpendicular to a first plane defined by an upper surface of the plurality of patterned features, wherein the ions are further delivered parallel to a second plane defined by the first sidewall, and wherein the ions impact the area of roughness.

In yet another aspect, an ion beam implanter may be operable to perform an ion beam treatment to a plurality of patterned features on a semiconductor substrate by delivering ions at a non-zero angle relative to a perpendicular to a plane defined by the semiconductor substrate, wherein the plurality of patterned features is formed over a stack of layers, wherein each of the plurality of patterned features includes a first sidewall and a second sidewall, and wherein an area of roughness present along the first sidewall or the second sidewall is impacted by the ions.

### BRIEF DESCRIPTION OF THE DRAWINGS

The accompanying drawings illustrate exemplary approaches of the disclosure, including the practical application of the principles thereof, as follows:

FIG. 1A is a side cross-sectional view of a stack of layers of a semiconductor device including a plurality of patterned lines, according to embodiments of the present disclosure;

FIG. 1B is a top view of the stack of layers of the semiconductor device including a plurality of patterned lines, according to embodiments of the present disclosure;

FIG. 2A is a top view of the stack of layers of the semiconductor device including the plurality of patterned lines during an ion treatment process, according to embodiments of the present disclosure;

FIG. 2B is a side cross-sectional view of the stack of layers of the semiconductor device including the plurality of patterned lines during the ion treatment process, according to embodiments of the present disclosure;

FIG. 3 is a top view of the stack of layers of the semiconductor device including the plurality of patterned lines following the treatment process to minimize surface roughness, according to embodiments of the present disclosure;

FIG. 4 is a side cross-sectional view of the stack of layers of the semiconductor device including the plurality of patterned lines during an etch process to form a plurality of trenches, according to embodiments of the present disclosure;

FIG. 5 illustrates a schematic diagram of a processing apparatus according to embodiments of the present disclosure; and

FIG. 6 shows a semiconductor processing apparatus according to embodiments of the disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods and systems in accordance with the present disclosure will now be described more fully hereinafter with reference to the accompanying drawings, where various embodiments are shown. The methods and systems may be embodied in many different forms and are not to be construed as being limited to the embodiments set forth herein. Instead, these embodiments are provided so the disclosure will be thorough and complete, and will fully convey the scope of the methods to those skilled in the art.

To address the deficiencies of the prior art described above, embodiments of the present disclosure advantageously reduce line/space LWR/LER of a plurality of patterning features, such as EUV lithography patterned lines, using an ion beam implantation at high incident angles (e.g., between 50°-80) along the length of the EUV-patterned lines. In some examples, decreases of over 30% in both LER and LWR can be achieved, while maintaining pattern critical dimensions (CDs). These LER and LWR improvements transfer from the EUV-patterned lines to subsequently etched layers.

The LER and LWR improve over a range of spatial frequencies, with the greatest improvement in the micron-scale frequencies. Furthermore, the angled ion beam treatment densifies the materials of the EUV-patterned lines through outgassing of volatiles and chemical re-ordering, affecting tension forces in the EUV-patterned lines and improving the LER and LWR. This patterning improvement has been demonstrated with metal oxide resists (MOR), chemically amplified resists (CAR), soft carbon-based film layers, hardmask materials, etc.

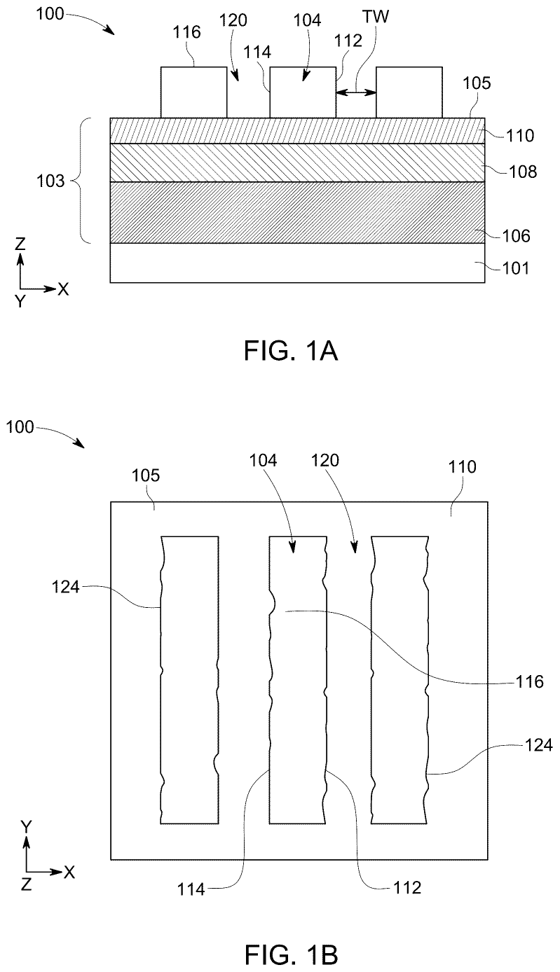

FIG. 1A depicts a portion of a semiconductor device (hereinafter “device”) 100, according to one or more embodiments. The device 100 may include a stack of layers 103 on a semiconductor substrate 101, and a plurality of patterning features or lines 104 formed atop an upper surface 105 of the stack of layers 103. Although non-limiting, the stack of layers 103 may include a first underlayer 106, a film layer 108 over the first underlayer 106, and a second underlayer 110 over the film layer 108. Although non-limiting, the first underlayer 106 may be a silicon containing base hardmask (e.g., amorphous silicon (aSi), silicon carbide (SiC), silicon boride (SiB), silicon dioxide (SiO2), silicon nitride (SiN), silicon-oxynitride (SiON), etc.), the film layer 108 may be a carbon film (e.g., advanced patterning film (APF), spin on hardmask (SOH), amorphous carbon layer (ACL), etc.), and the second underlayer 110 may be a carbon, organic/inorganic underlayer for adhesion and dose reduction. In other embodiments, the second underlayer 110 may be amorphous silicon. Although non-limiting, the second underlayer 110 may be approximately 5-10 nm thick (e.g., in the z-direction) in some embodiments. Each of the layers of the stack of layers 103 may be formed using either spin-on or deposition techniques. Furthermore, the stack of layers 103 may include additional layers not shown.

In some embodiments, the plurality of patterned lines 104 are formed from a photoresist layer into a desired pattern and shape. For example, each of the plurality of patterned lines 104 may include a first sidewall 112 opposite a second sidewall 114, and an upper surface 116 extending between the first and second sidewalls 112, 114. The plurality of patterned lines 104 may be defined by a plurality of openings or trenches 120 formed selective to the upper surface 105 of the stack of layers 103. The patterned lines 104 may have a long axis extending in the y-direction and a short axis extending in the x-direction, wherein a length of the patterned lines 104 along the long axis is greater than a width of the patterned lines 104 along the short axis. In the embodiment shown, the trench width is substantially the same for each of the trenches 120 of the device 100.

The plurality of patterned lines 104 may be formed from a metal-oxide resist (MOR). In another embodiment, the plurality of patterned lines 104 are formed from a chemically amplified resist (CAR). In the case of a CAR, the film layer 108 may not be present. Instead, the second underlayer 110 may be formed directly atop the first underlayer 106. Although non-limiting, in various embodiments, the CAR may be spun-on, while the MOR is spun-on or deposited.

In other embodiments, the plurality of patterned lines 104 may be formed from a carbon-based film layer, which can be spun-on or deposited (e.g., via chemical vapor deposition (CVD)) on the stack of layers 103. In still other embodiments, the plurality of patterned lines 104 may be formed from a hardmask material, such as silicon oxide (e.g., formed via deposition from a tetraethyl orthosilicate precursor gas), silicon nitride, silicon oxynitride, tungsten carbide, or a carbon-based material. Although non-limiting, the hardmask material(s) may be deposited by CVD.

As better shown in the top view of FIG. 1B, one or more areas of roughness 124 may be present along at least one of the first sidewall 112 and the second sidewall 114 of the patterned lines 104. The area of roughness 124 may be areas containing protrusions and/or indentations along the surfaces of the patterned lines 104 after formation. The area(s) of roughness 124 can take on any variety of shapes and sizes.

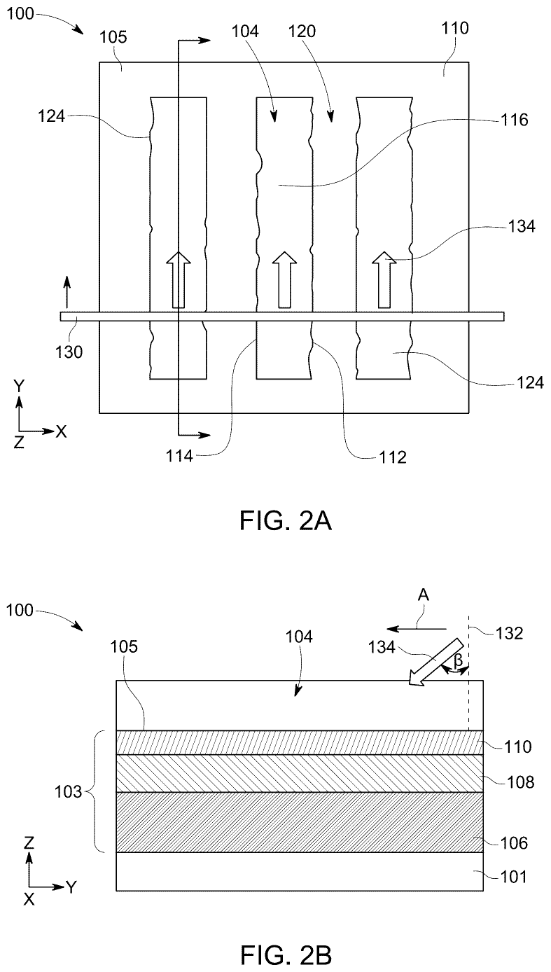

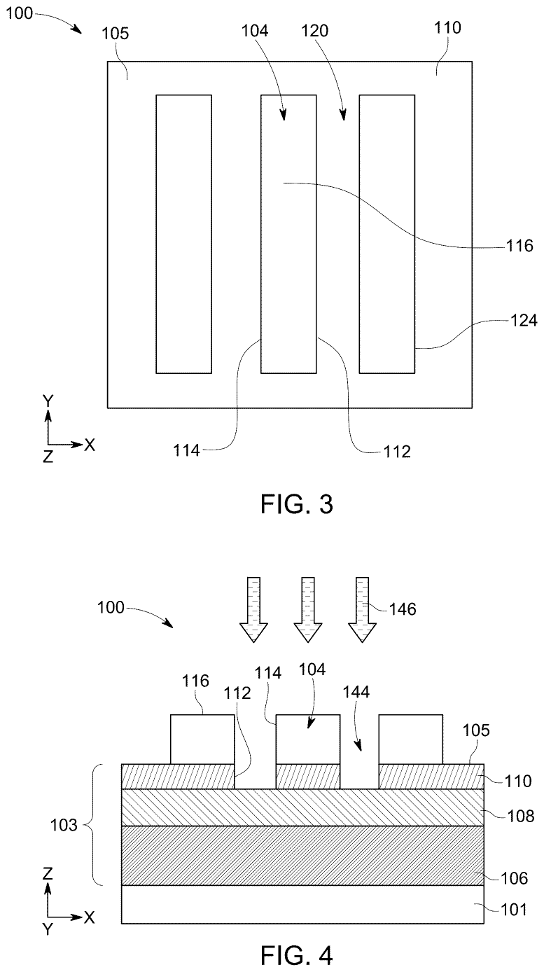

To mitigate these areas of roughness 124, as shown in FIGS. 2A-2B , an ion beam 130 may be delivered to the plurality of patterned lines 104 at a high angle (e.g., between 50°-85°) and along the long axis of the patterned lines 104. That is, the ion beam 130 may be delivered at a non-zero angle (β) relative to a perpendicular 132 (FIG. 2B) to a first plane defined by the substrate 101, and may also be delivered parallel to a second plane defined by first sidewall 112. In some embodiments, angled ions 134 from the ion beam 130 may impact the area of roughness 124 as the ion beam 130 is moving/scanning the patterned lines 104. In various embodiments, the ion beam 130 may be a ribbon beam or a spot beam. Although non-limiting, the non-zero angle relative to the perpendicular may be between 50°-85°, and the ion beam 130 may be delivered at an energy between 0.2 keV and 5 keV. Furthermore, the angled ions 134 may include an inert or other gas species, such as xenon (Xe), silicon (Si), argon (Ar), helium (He), nitrogen (N2), etc. Other chemistries may be used in alternative embodiments. Following the ion beam treatment, the area of roughness 124 may be substantially reduced/smoothed, as demonstrated in FIG. 3. Advantageously, the width, or CD, of each trench 120 is not increased as a result of the treatment process.

The area of roughness 124 may be minimized because the angled ions 134 break bonds of the photoresist layer and volatiles are outgassed, which contributes to volume loss/shrinkage. The angled ions 134 may further cause carbonization and re-ordering of the photoresist, leading to thermal stabilization/resist freeze and densification. Tension changes may also occur as a result of treatment with angled ions 134, contributing to improvement of long-range order and low-frequency LWR. However, any sputtering of the photoresist as a result of the angled ions 134 is not significant enough to contribute to CD and thickness changes.

As shown in FIG. 4, a plurality of trenches 144 may then be formed in one or more layers of the stack of layers 103. In some embodiments, the trenches 144 may be formed using an etch process 146, e.g., a reactive ion etch (RIE), which delivers ions through the trenches 120 formed by the patterned resist lines 104. The etch process 146 may be vertical or delivered at an angle. Advantageously, the improvements in LER and LWR of the patterned lines 104 as a result of the angled ions 134 are transferred to the stack of layers 103 during subsequent patterning, which ultimately decreases device defectivity and increases yield.

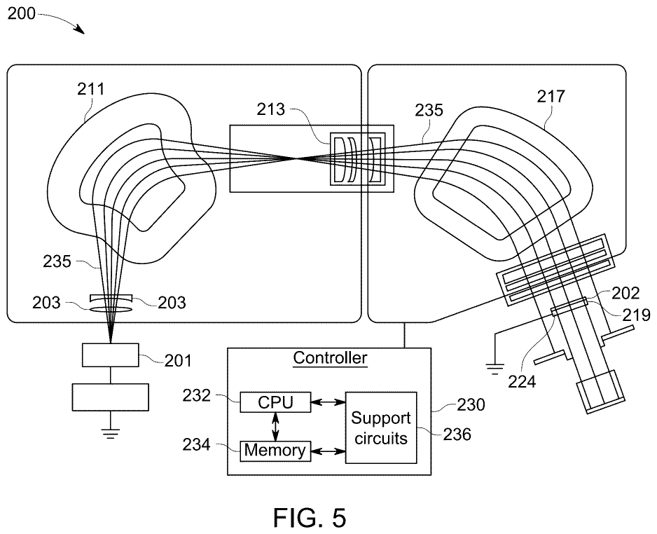

FIG. 5 illustrates a schematic diagram of a processing apparatus 200 useful to perform processes described herein. One example of a beam-line ion processing apparatus is the Varian VIISTA® Trident, available from Applied Materials Inc., Santa Clara, CA. The processing apparatus 200 may include an ion source 201 for generating ions. For example, the ion source 201 may provide an ion beam treatment, such as the angled ions 134 from the ion beam 130 demonstrated in FIGS. 2A-2B.

The processing apparatus 200 may also include a series of beam-line components. Examples of beam-line components may include extraction electrodes 203, a magnetic mass analyzer 211, a plurality of lenses 213, and a beam parallelizer 217. The processing apparatus 200 may also include a platen 219 for supporting a substrate 202 to be processed. In some embodiments, the platen 219 may be heated using an external or embedded heating element 224, such as a resistive heater, or may be heated using radiant heat, such as heating lamps disposed above or below the platen 219. In other embodiments, the heating element may additionally, or alternatively, be located in a load lock chamber or a separate pre-heat chamber to pre-heat the substrate 202 before it reaches the platen 219. Even with a pre-heat, the platen 219 may include the internal heating element 224. The substrate 202 may be the same as the substrate 102 described above. The substrate 202 may be moved in one or more dimensions (e.g. translate, rotate, tilt, etc.) by a component sometimes referred to as a rotating platen or “roplat” (not shown). It is also contemplated that the processing apparatus 200 may be configured to perform heated treatment processes to provide for improved control of treatment characteristics, such as the ion trajectory and ion treatment energy utilized to treat the substrate 202.

In operation, ions of the desired species, for example, dopant ions, are generated and extracted from the ion source 201. Thereafter, the extracted ions 235 travel in a beam-like state along the beam-line components and may be directed to be incident on the substrate 202. Similar to a series of optical lenses that manipulate a light beam, the beam-line components manipulate the extracted ions 235 along the ion beam. In such a manner, the extracted ions 235 are manipulated by the beam-line components while the extracted ions 235 are directed toward the substrate 202. It is contemplated that the apparatus 200 may provide for improved mass selection to process with desired ions while reducing the probability of undesirable ions (impurities) being incident on the substrate 202.

In some embodiments, the processing apparatus 200 can be controlled by a processor-based system controller such as controller 230. For example, the controller 230 may be configured to control beam-line components and processing parameters associated with beam-line ion treatments. The controller 230 may include a programmable central processing unit (CPU) 232 that is operable with a memory 234 and a mass storage device, an input control unit, and a display unit (not shown), such as power supplies, clocks, cache, input/output (I/O) circuits, and the like, coupled to the various components of the processing apparatus 200 to facilitate control of the substrate processing. The controller 230 also includes hardware for monitoring substrate processing through sensors in the processing apparatus 200, including sensors monitoring the substrate position and sensors configured to receive feedback from and control a heating apparatus coupled to the processing apparatus 200. Other sensors that measure system parameters such as substrate temperature and the like, may also provide information to the controller 230.

To facilitate control of the processing apparatus 200 described above, the CPU 232 may be one of any form of general-purpose computer processor that can be used in an industrial setting, such as a programmable logic controller (PLC), for controlling various chambers and sub-processors. The memory 234 is coupled to the CPU 232 and the memory 234 is non-transitory and may be one or more of readily available memory such as random access memory (RAM), read only memory (ROM), floppy disk drive, hard disk, or any other form of digital storage, local or remote. Support circuits 236 may be coupled to the CPU 232 for supporting the processor in a conventional manner. Ion processing and other processes are generally stored in the memory 234, typically as a software routine. The software routine may also be stored and/or executed by a second CPU (not shown) that is remotely located from the hardware being controlled by the CPU 232.

The memory 234 is in the form of computer-readable storage media that contains instructions, that when executed by the CPU 232, facilitates the operation of the apparatus 200. The instructions in the memory 234 are in the form of a program product such as a program that implements the method of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

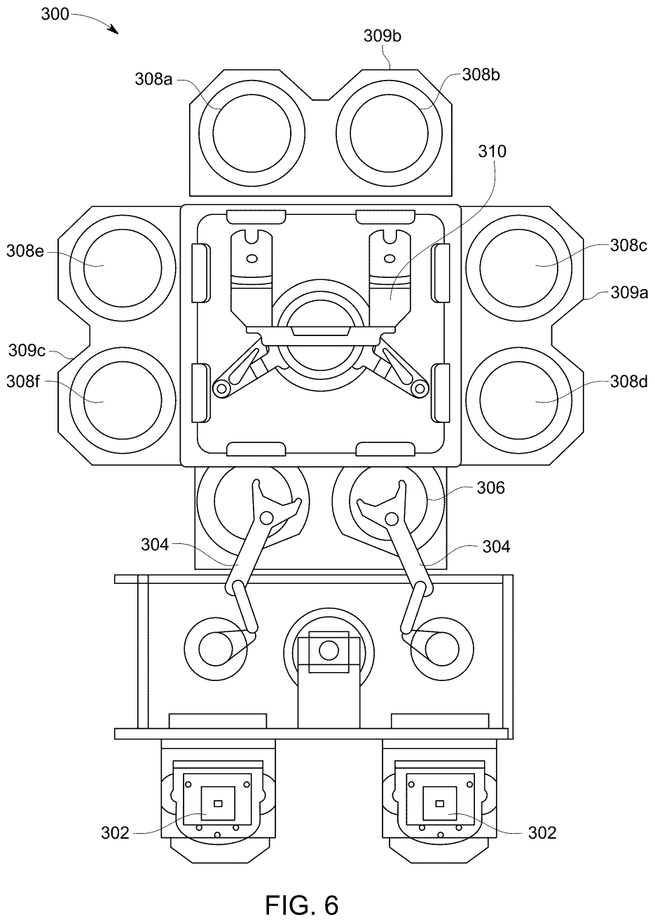

FIG. 6 illustrates a top plan view of one embodiment of another processing system 300 including a plurality of chambers according to some embodiments. As shown, a pair of front opening unified pods 302 supply substrates of a variety of sizes that are received by robotic arms 304 and placed into a low-pressure holding area 306 before being placed into one of the substrate processing chambers 308a-f, positioned in tandem sections 309a-c. A second robotic arm 310 may be used to transport the substrate wafers from the holding area 306 to the substrate processing chambers 308a-f and back. Each substrate processing chamber, 308a-f, can be outfitted to perform a number of substrate processing operations described herein such as ion beam treatment, pre-clean, anneal, plasma processing, degas, orientation, and other substrate processes.

The substrate processing chambers 308a-f may include one or more system components for depositing, treating, growing, annealing, curing, implanting, and/or etching the substrate and/or a material layer on the substrate or wafer. In one configuration, two pairs of the processing chambers, for example 308a-b, may be used to treat the substrate and/or the material layers formed atop the substrate using a beamline ion beam treatment, such as the angled ions 134 from the ion beam 130 demonstrated in FIGS. 2A-2B . In some embodiments, the beam-line ion processing apparatus 200 may be present within processing chamber 308a or 308b.

Another two pairs of the processing chambers, for example, 308c-d, may be used to deposit materials/layers of the stack of layers 103, as well as to form the layer/film from which the plurality of patterned lines 104 are formed on the stack of layers 103. Another two pairs of the processing chambers, for example, 308e-f, may be used to perform one or more post-ion treatment etch processes, such as reactive ion etch (RIE) to form the plurality of trenches 144 through the stack of layers 103.

Any one or more of the processes described may be carried out in additional chambers separated from the fabrication system shown in different embodiments. It will be appreciated that additional configurations of deposition, ion treating, growing, etching, annealing, and curing chambers for substrates and material layers are contemplated by the processing system 300. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed sequentially in multiple chambers while maintaining a particular vacuum environment between discrete processes.

The processing system 300, or more specifically, chambers incorporated into the processing system 300 or other processing systems, may be used to produce structures according to some embodiments of the present disclosure.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method comprising:
providing a plurality of patterned features over a stack of layers on a semiconductor substrate, wherein each of the plurality of patterned features includes a sidewall, and wherein an area of roughness is present along the sidewall of at least one patterned feature of the plurality of patterned features; and
performing an ion beam treatment to the plurality of patterned features by delivering ions at a non-zero angle relative to a perpendicular to a plane defined by the semiconductor substrate, wherein the ions impact the area of roughness.

2. The method of claim 1, wherein the ion beam treatment comprises directing an ion beam at the non-zero angle along a long axis of the plurality of patterned features, and wherein the non-zero angle is between 50° and 85°.

3. The method of claim 1, further comprising forming a plurality of trenches in the stack of layers by performing an etch process following the ion beam treatment.

4. The method of claim 1, wherein the plurality of patterned features is formed from a photoresist.

5. The method of claim 4, wherein the photoresist is a metal-oxide resist or a chemically amplified resist.

6. The method of claim 1, wherein the plurality of patterned features is formed from a carbon-based film layer.

7. The method of claim 1, wherein the plurality of patterned features are formed from silicon oxide, silicon nitride, or tungsten carbide.

8. The method of claim 1, wherein performing the ion beam treatment comprises delivering at least one of the following ion species to the plurality of patterned features: argon, silicon, and xenon.

9. The method of claim 1, wherein performing the ion beam treatment comprises delivering the ions at an implant energy between 0.2 keV and 5.0 keV.

10. A method for minimizing surface roughness of a patterned feature, the method comprising:
providing a plurality of patterned features over a stack of layers on a semiconductor substrate, wherein each of the plurality of patterned features includes a first sidewall and a second sidewall, and wherein an area of roughness is present along the first sidewall or the second sidewall of at least one patterned feature of the plurality of patterned features; and
performing an ion beam treatment to the plurality of patterned features by delivering ions at a non-zero angle relative to a perpendicular to a first plane defined the semiconductor substrate, wherein the ions are further delivered parallel to a second plane defined by the first sidewall, and wherein the ions impact the area of roughness.

11. The method of claim 10, further comprising forming a plurality of trenches in the stack of layers by performing an etch process following the ion beam treatment.

12. The method of claim 10, wherein the plurality of patterned features is formed from a metal-oxide resist or a chemically amplified resist.

13. The method of claim 10, wherein the plurality of patterned features is formed from one of: a carbon-based film layer, or a hardmask material.

14. The method of claim 13, wherein the hardmask material is one of silicon oxide, silicon nitride, silicon oxynitride, or tungsten carbide.

15. The method of claim 10, wherein the non-zero angle is between 50° and 85°, wherein performing the ion beam treatment comprises delivering at least one of the following ion species to the plurality of patterned features: argon, silicon, and xenon, and wherein performing the ion beam treatment comprises delivering the ions at an implant energy between 0.2 keV and 5.0 keV.

16. An ion beam implanter operable to:
perform an ion beam treatment to a plurality of patterned features on a semiconductor substrate by delivering ions at a non-zero angle relative to a perpendicular to a plane defined by the semiconductor substrate, wherein the plurality of patterned features is formed over a stack of layers, wherein each of the plurality of patterned features includes a first sidewall and a second sidewall, and wherein an area of roughness present along the first sidewall or the second sidewall is impacted by the ions.

17. The ion beam implanter of claim 16, wherein delivering the ions to the plurality of patterned features further comprises directing an ion beam at the non-zero angle along a long axis of the plurality of patterned features, and wherein the non-zero angle is between 50° and 85°.

18. The ion beam implanter of claim 16, wherein the plurality of patterned features is formed from one of: a metal oxide resist, a chemically amplified resist, a carbon-based film layer, or a hardmask material.

19. The ion beam implanter of claim 18, wherein the hardmask material is one of silicon oxide, silicon nitride, silicon oxynitride, or tungsten carbide.

20. The ion beam implanter of claim 16, wherein performing the ion beam treatment comprises delivering at least one of the following ion species to the plurality of patterned features: argon, silicon, and xenon, and wherein performing the ion beam treatment comprises delivering the ions at an implant energy between 0.2 keV and 5.0 keV.
